(19) United States
(12) Patent Application Publication
(10) Pub. No.: US 2006/0232802 A1
(43) Pub. Date: Oct. 19, 2006

(54) Color selection process and system

(76) Inventors: Melinda Gray, Lorain, OH (US); Rosemary Niewolak, Hudson, OH (US); Barbara Richardson, Fairview Park, OH (US)

Correspondence Address: THE GLIDDEN COMPANY, 15885 WEST SPRAGUE ROAD, STRONGVILLE, OH, 44136, US

(21) Appl. No.: 11/396,449

(22) Filed: Apr. 3, 2006

Related U.S. Application Data
(60) Provisional application No. 60/667,892, filed on Apr. 1, 2005.

(51) Int. Cl. G03F 3/08; G06F 15/00

(52) U.S. Cl. 358/1.9; 358/518; 382/167

(57) ABSTRACT

A process for producing a color scheme recommendation for at least a part of a structure to be painted which comprises the steps of: selecting, at a user terminal and from a first database on a remote server containing at least one image of structural archetypes stored in electronic format on a storage device, an archetype image that closely matches the structure to be painted, selecting, at the user terminal, a color(s) from a second database located at the remote server containing at least one color stored in electronic format on storage device; applying the color(s) at the remote server to the image to produce a color scheme; providing from an additional database a series of questions and advice for responding to each question to make the selection posed by the plurality of questions; displaying, on a display unit of the user terminal, of the at least part of a structure with the color applied; and providing information from which paint corresponding to the color(s) in the color scheme can be identified.

### CROSS-REFERENCE TO RELATED APPLICATION

This application claims priority under 35 U.S.C. § 119 from U.S. Provisional Application Ser. No. 60/667,892 (filed Apr. 1, 2005, which is incorporated in its entirety by reference herein.

### FIELD OF THE DISCLOSURE

The present disclosure is directed to a process and system for computer assisted selection of color schemes for coating architectural surfaces.

Published patent applications 20010049591 and 20010049592 to Richard David Brunt et. al. and incorporated herein in their entirety disclose methods and systems for producing a color recommendation for a structure or part of a structure to be painted. These disclosures show selecting from a database containing images of structural archetypes stored on storage means of an archetype image that closely matches the structure to be painted, selecting a color or colors from a database comprising colors stored on storage means and applying the color or colors to the archetype to produce a color scheme and displaying the structure or part of the structure with the color applied.

In addition the user of color suggesting computer information for selecting paint would find it helpful to have suggestions and useful information to guide the user in making selections of color for painting structures.

### SUMMARY OF THE DISCLOSURE

The system involves computer assisted selection which can be through at least one display device operationally connected to at least one computer operating system operationally connected to at least a computer memory. The memory has resident therein or supplied from storage devices such as a hard drive, optical discs or jump drives at least two databases, one for architectural structural features and one for a color palette. The color palette is arranged into categories based on hue and at least two additional color characteristics.

### BRIEF DESCRIPTION OF THE DRAWINGS

FIGS. 1-29 are screen shots of the web pages at the web site suitable in one embodiment for the present disclosure showing the graphic user interfaces and the questions and advice supplied to assist in the selection of at least one color for structural artifacts selected at the web site.

FIG. 30 is a schematic diagram of the process and system of an embodiment of the present invention.

### DETAILED DESCRIPTION OF THE INVENTION

For example, for a color palette such as one for interior and/or exterior paints each color is uniquely identified by notation of a color system such as the Munsell color system, the CIE (Commision International l'Eclairage) CIELAB, Hynter “Lab”, Ostwald, DIN (Deutsche Industrie Normen, Adams and the like. For these color systems including those linked to human perception where color can be visualized from the color notations, color is three-dimensional. Hence all of these systems arrange color in a rational order that involves three axes using three numerical values. Therefore color description also involves three measurements. These are hue, chroma and value. Hue which is usually commonly meant by the term “color”, distinguishes red from yellow and blue. Chroma or intensity is the range from dull to brilliant and Value or light reflectance value is the range from dark to light.

The computer assistance provides the aforelisted devices with industry standard software through local operation so that the databases are on portable storage devices such as optical discs like compact discs or DVD discs or Jump drives or on local area networks LAN or a computer network consisting of a worldwide network of computer networks that use the TCP/IP network protocols to facilitate data transmission and exchange. An example of such a computer network is the internet which is at least a three level hierarchy composed of backbone networks, mid-level networks, and stub networks. These include at least commercial, (.com or .co), university (.ac or .edu) and other research networks (.org, .net) and military (.mil) networks and span many different physical networks around the world with various protocols but chiefly the Internet Protocol. Such networks can be accessed by command line interfaces such as telnet and FTP or the more modern protocols of HTML and HTTP and XML or other available protocols.

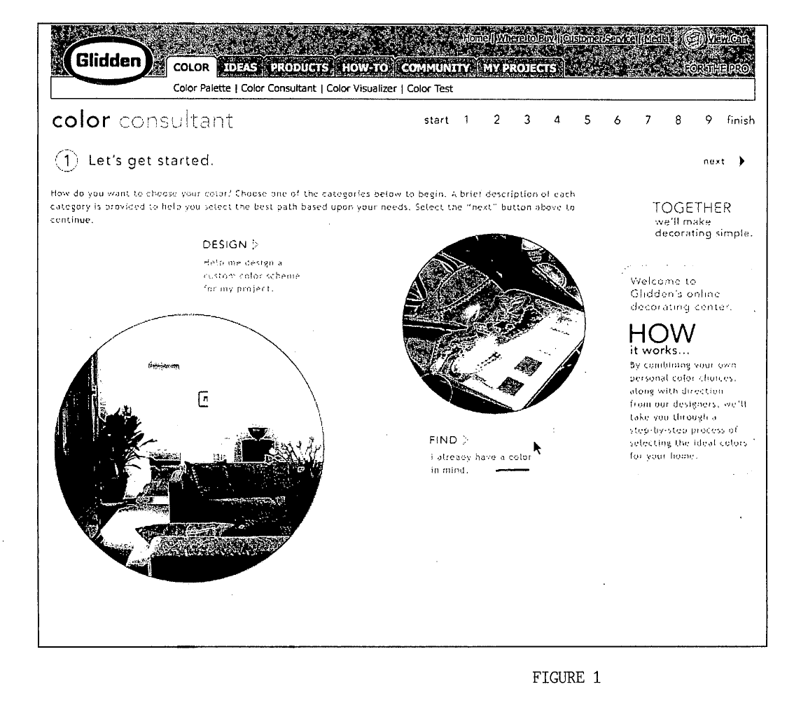

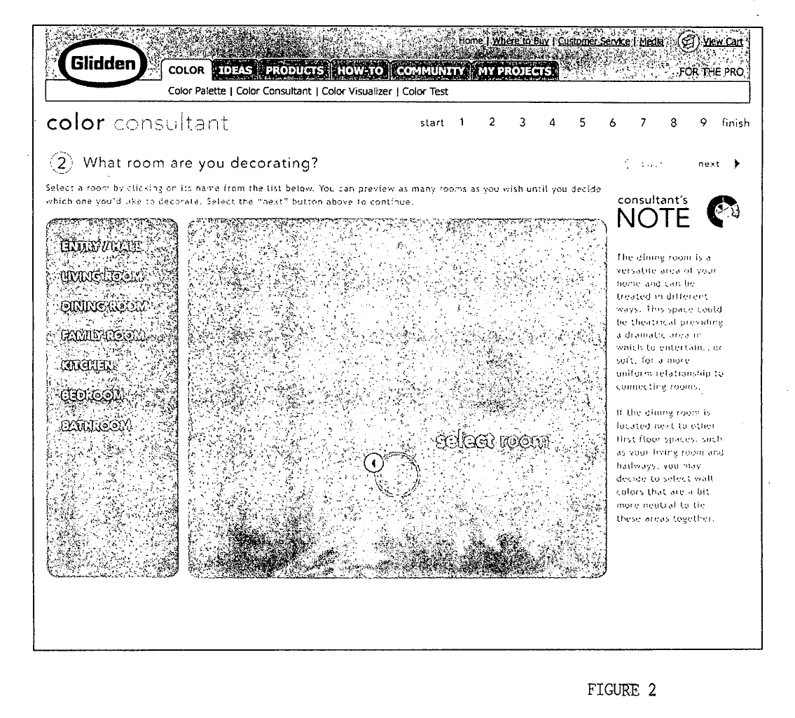

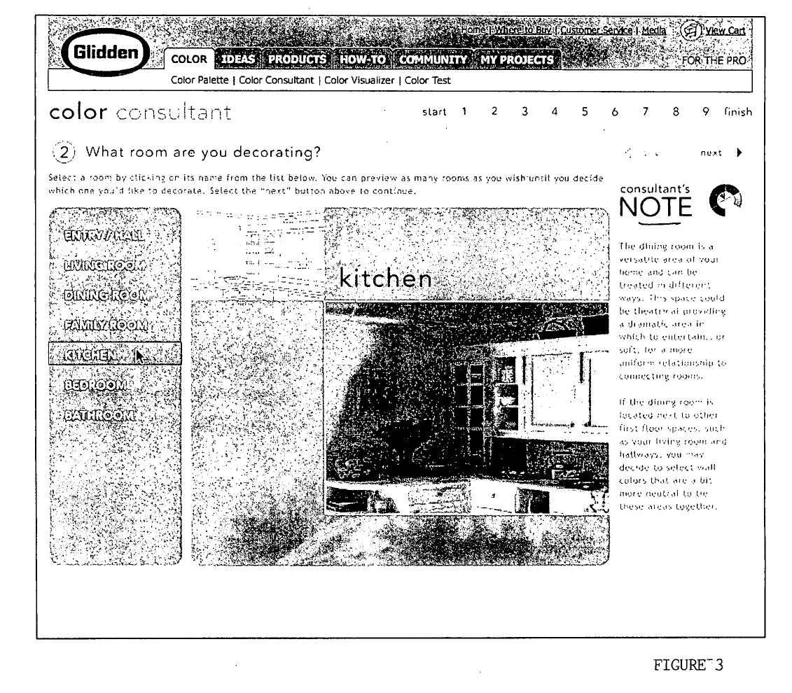

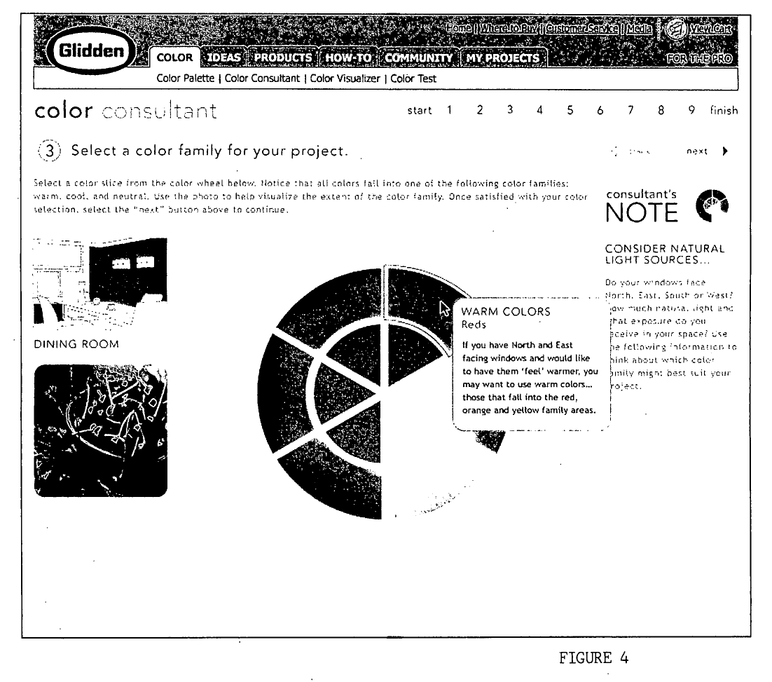

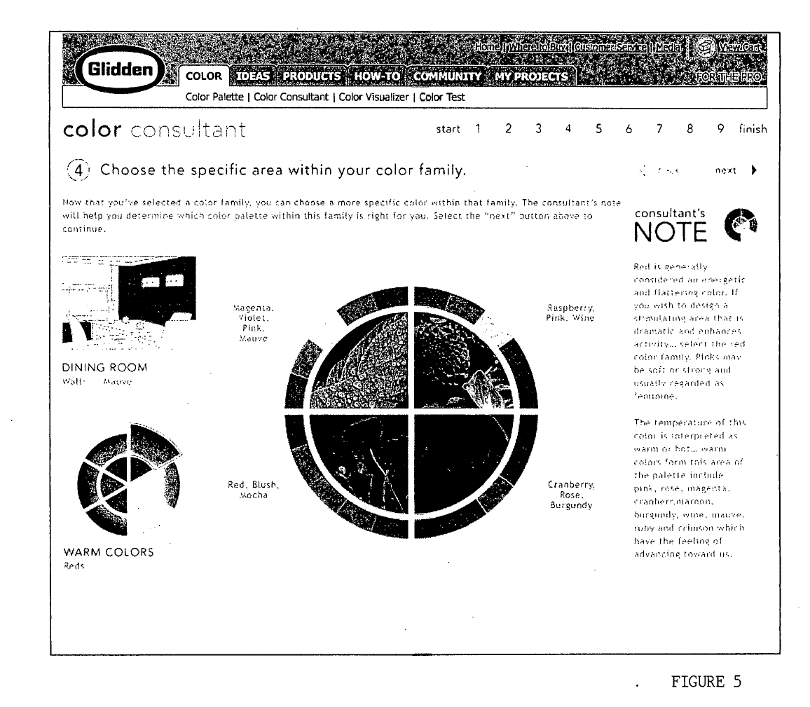

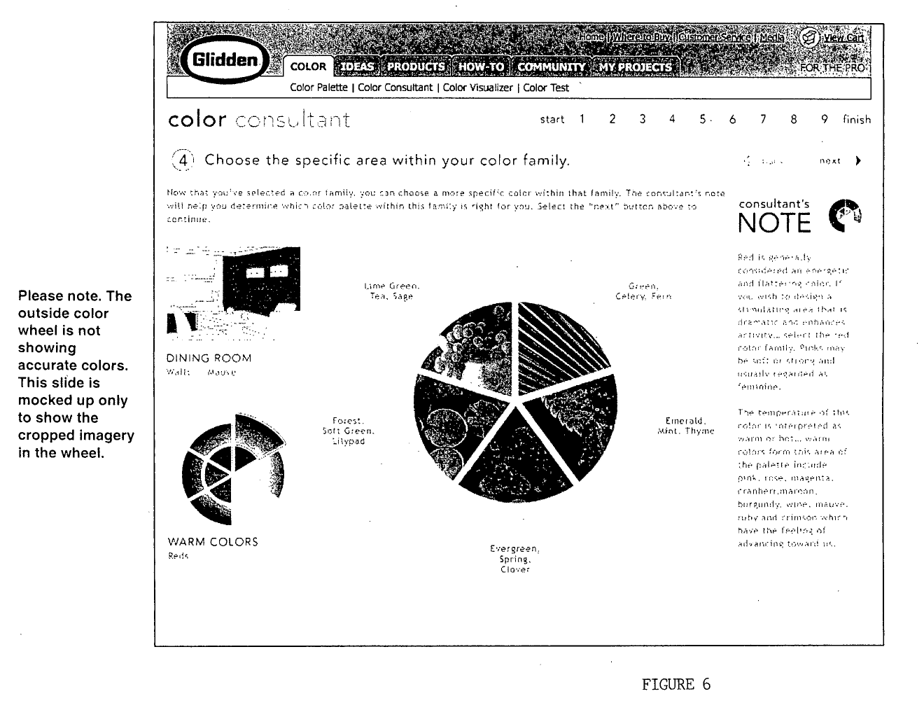

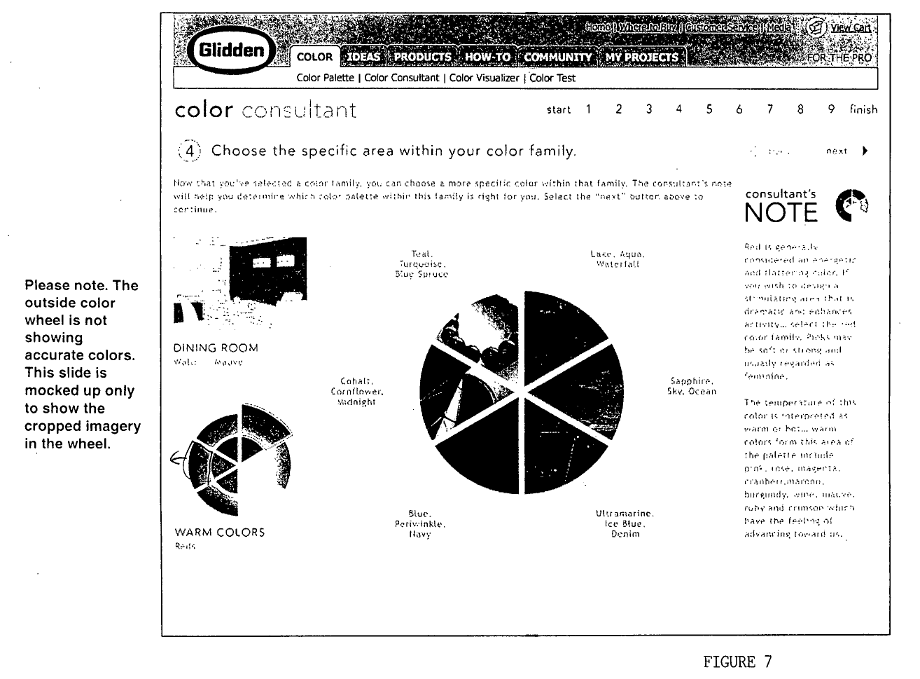

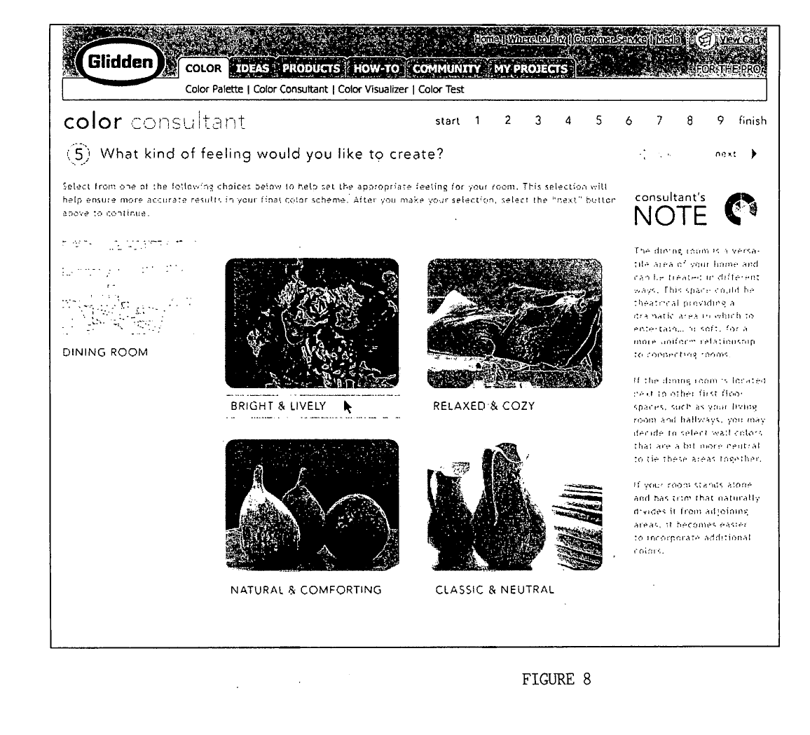

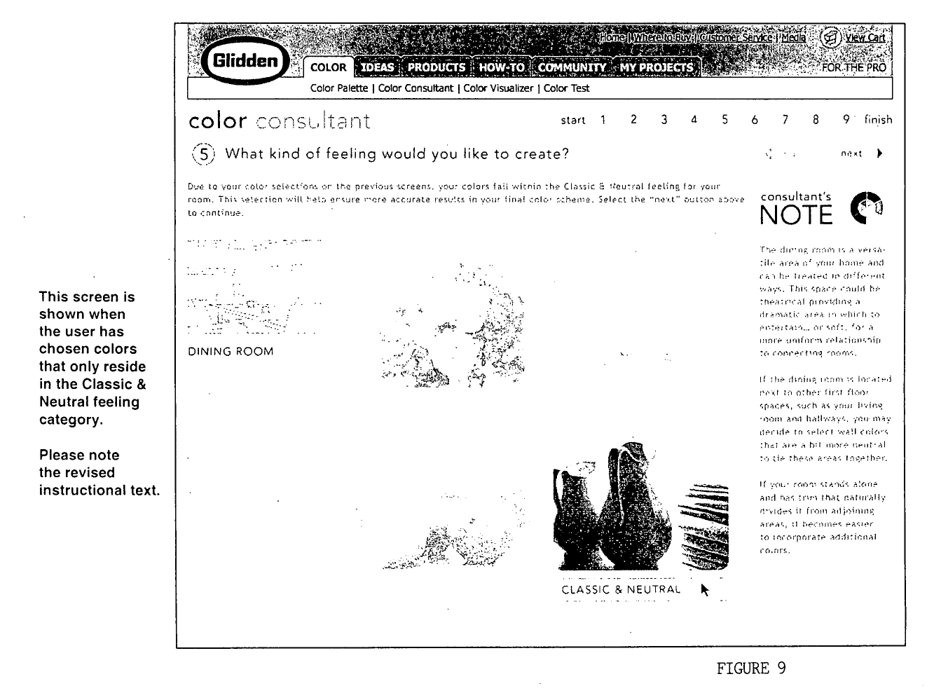

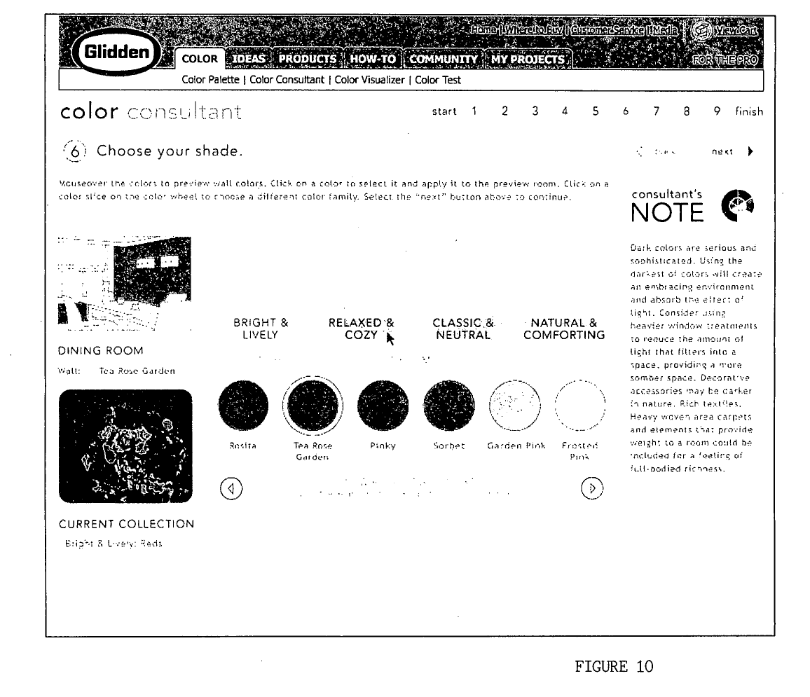

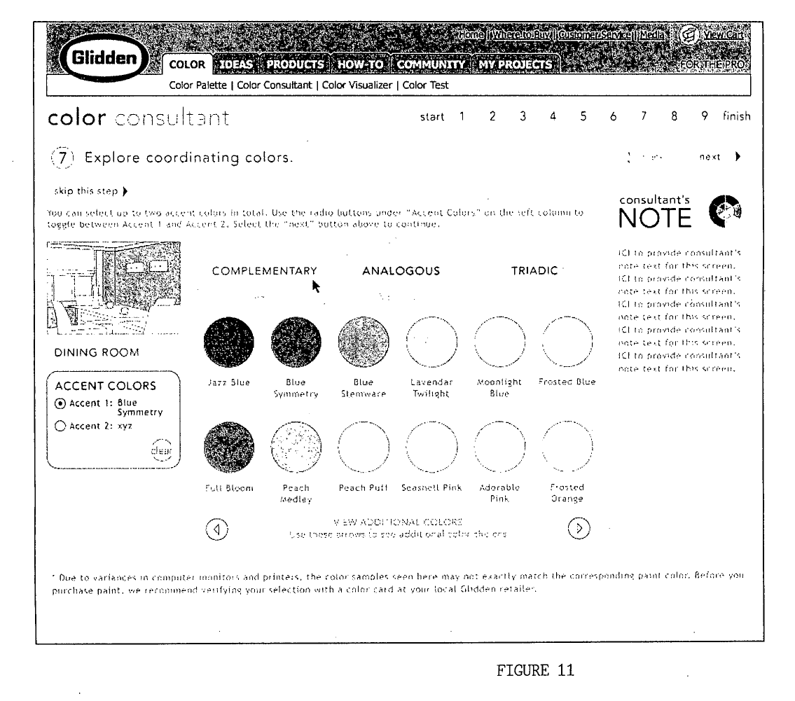

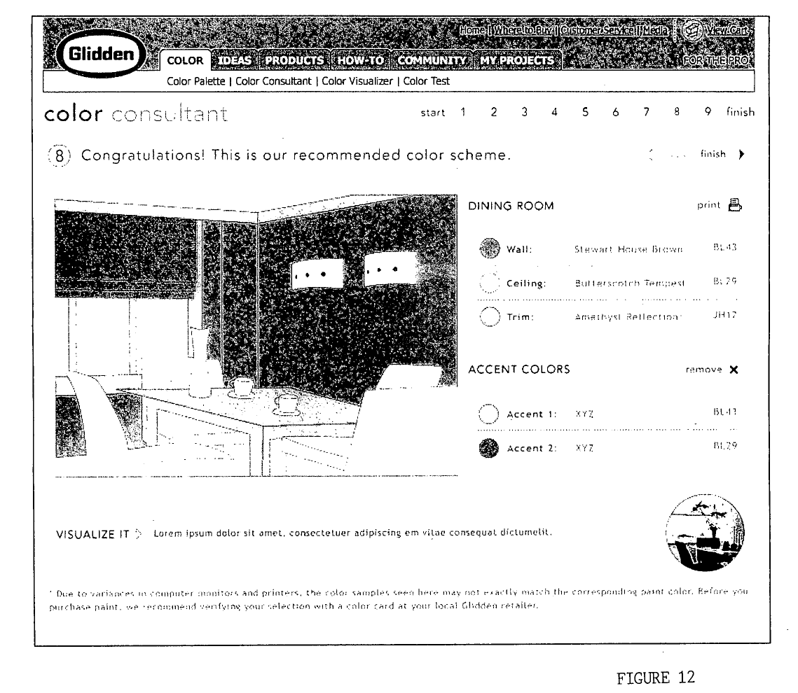

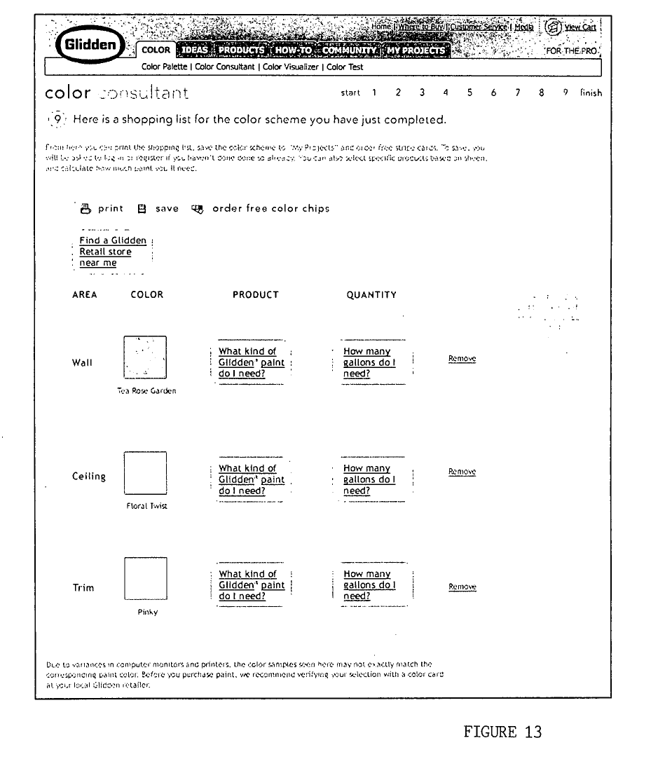

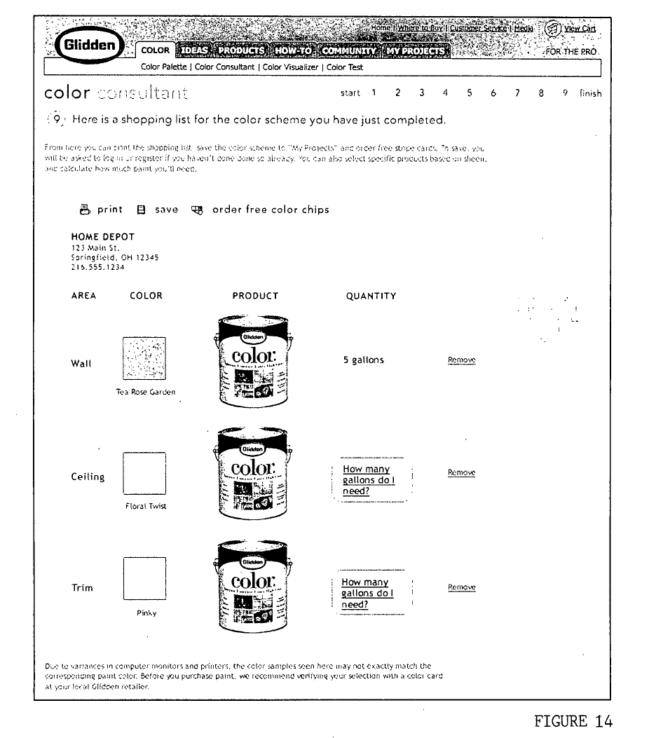

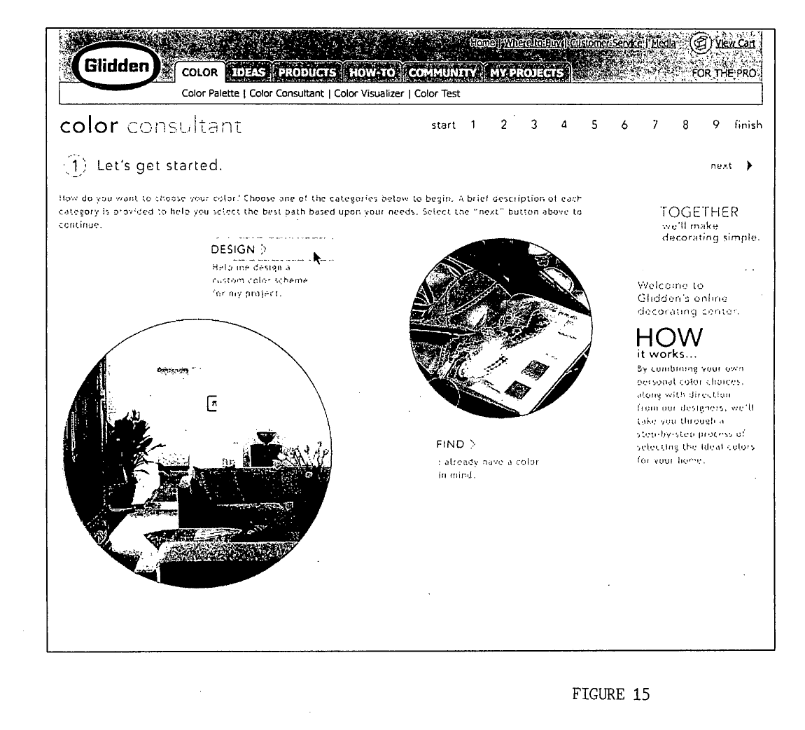

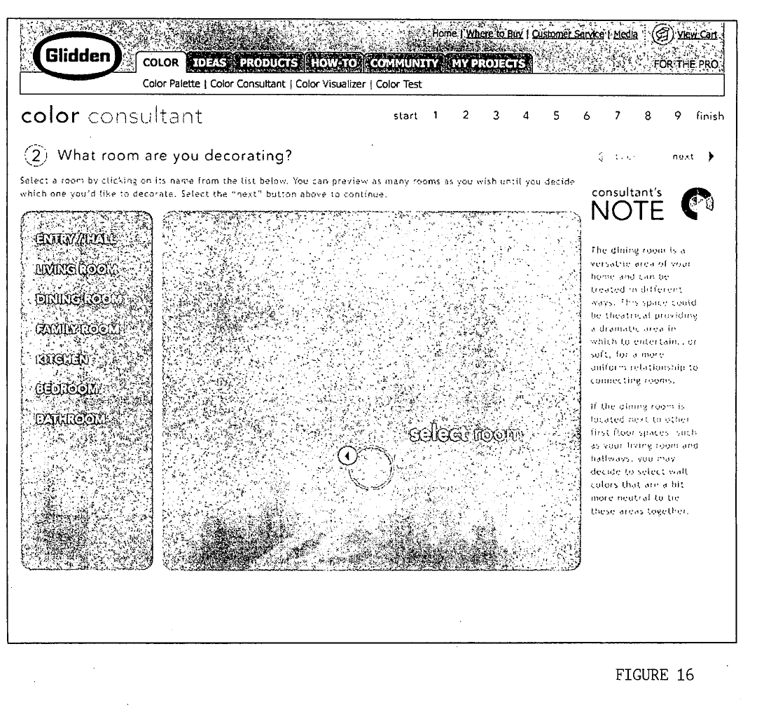

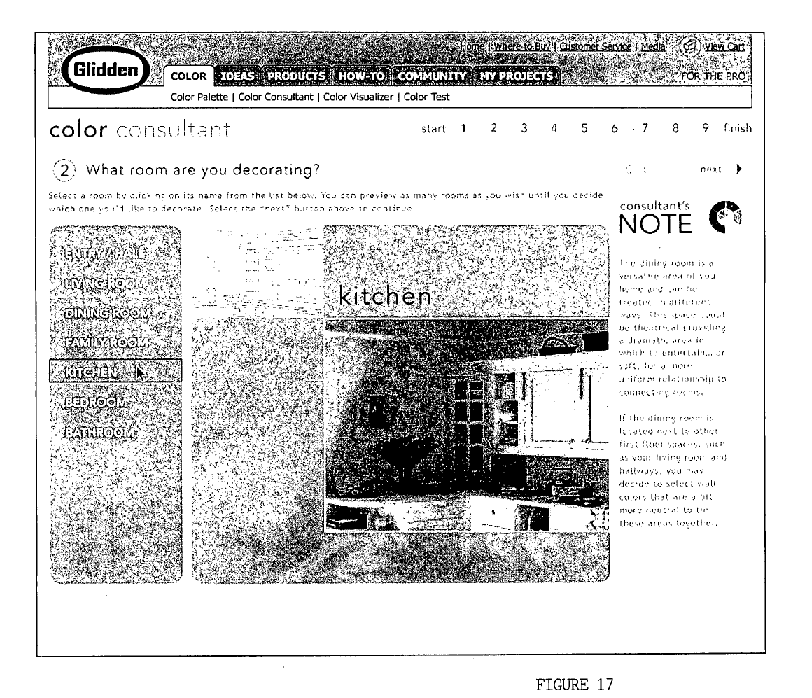

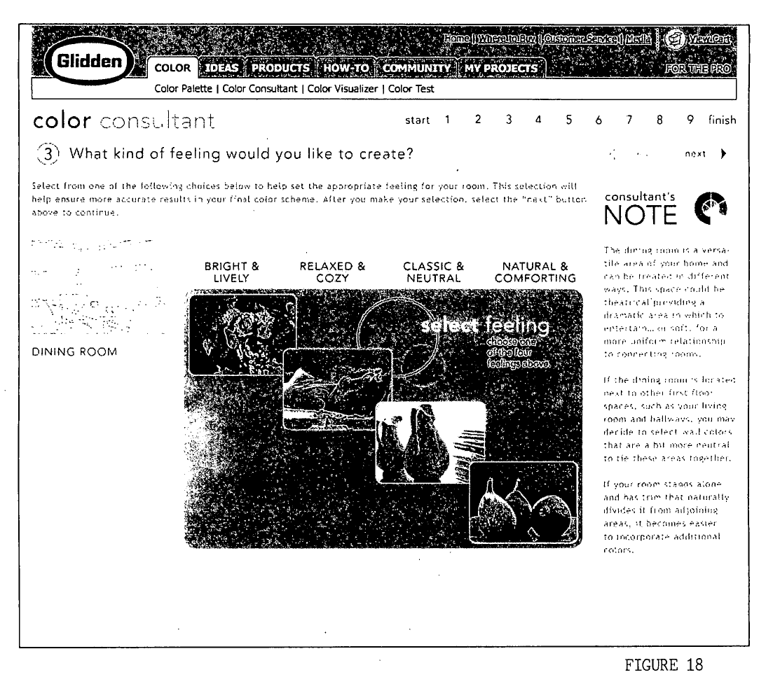

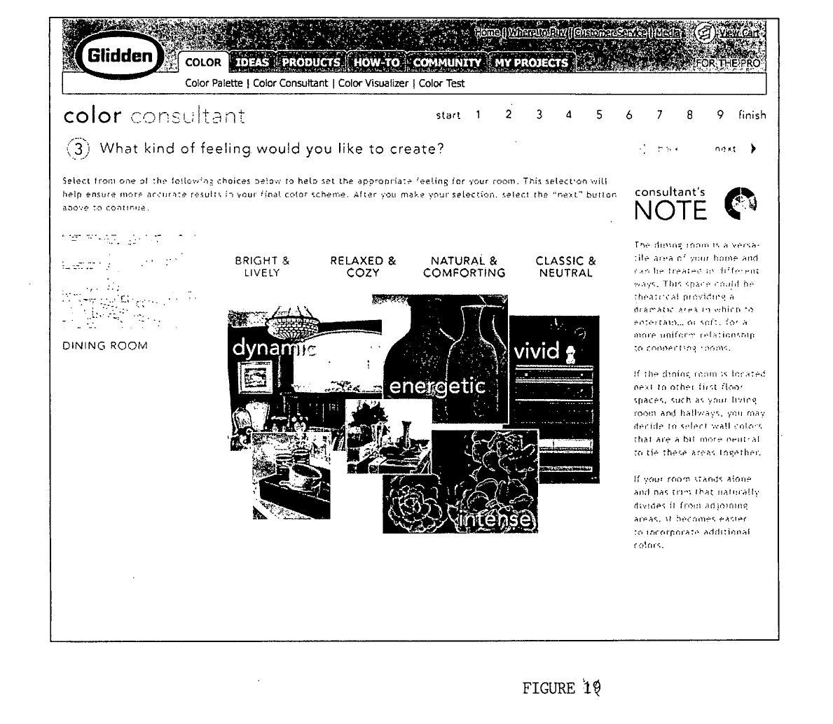

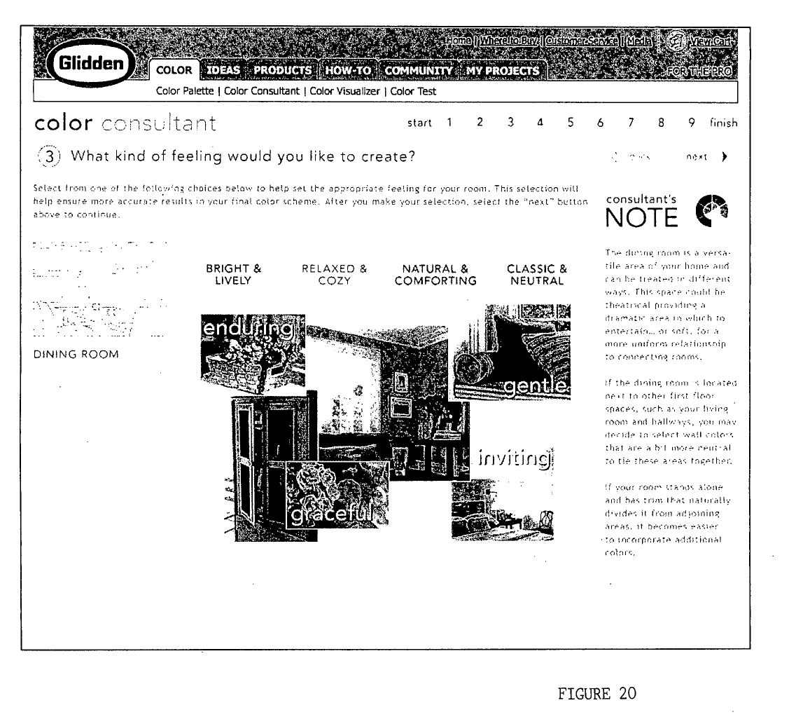

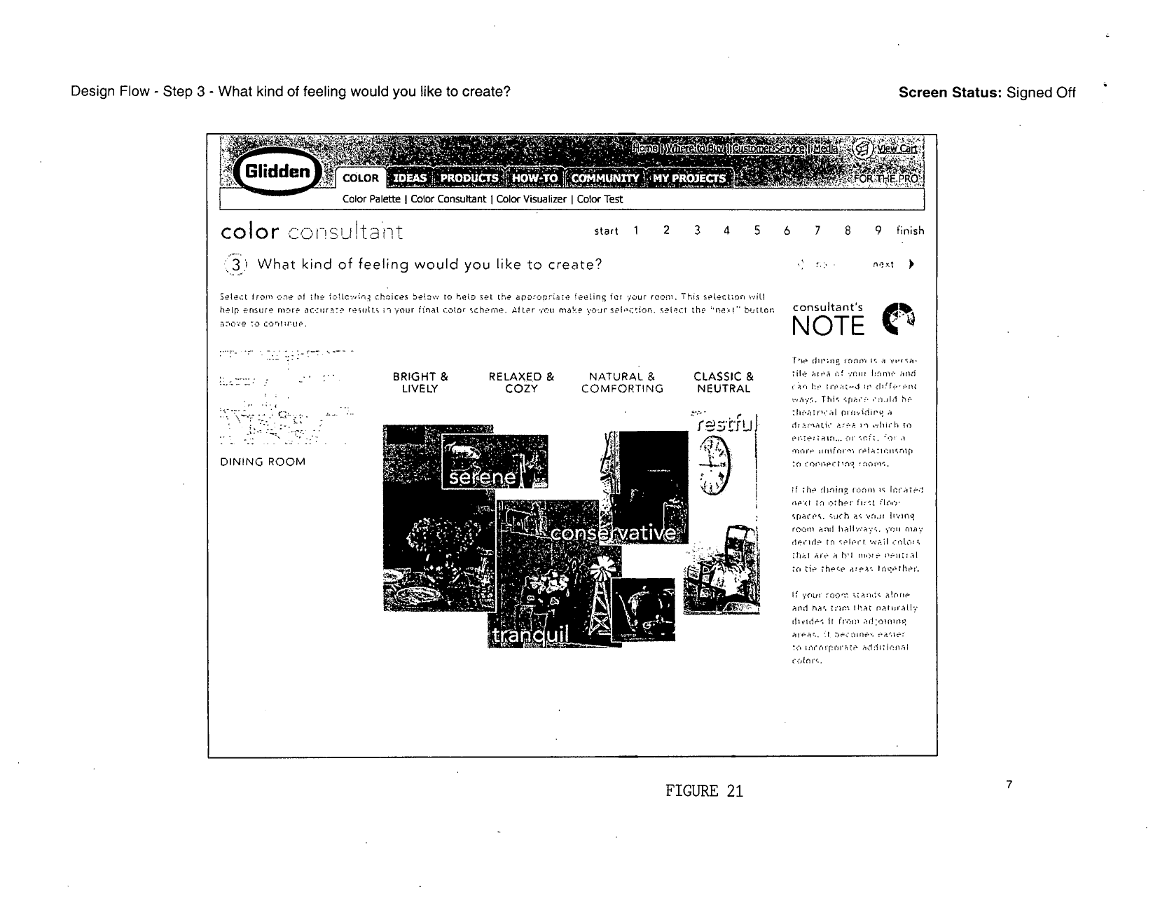

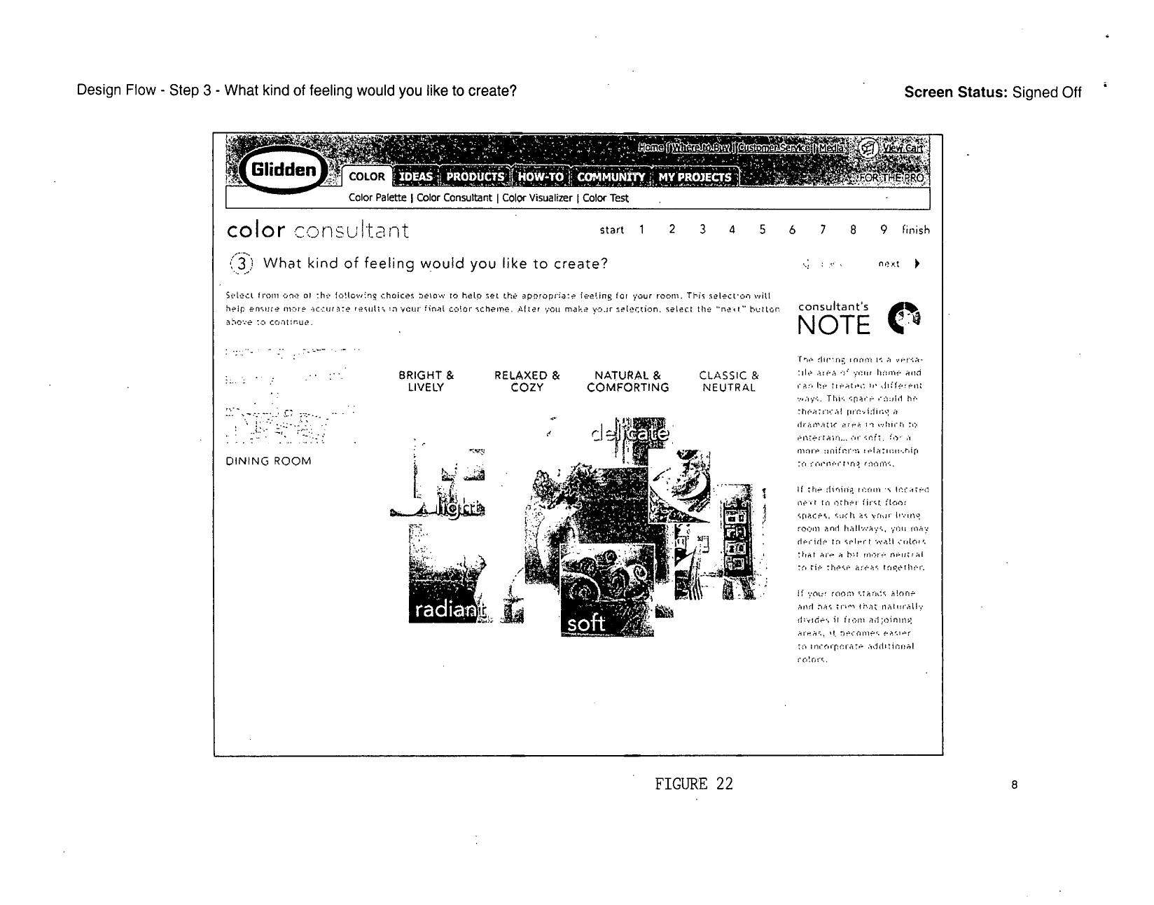

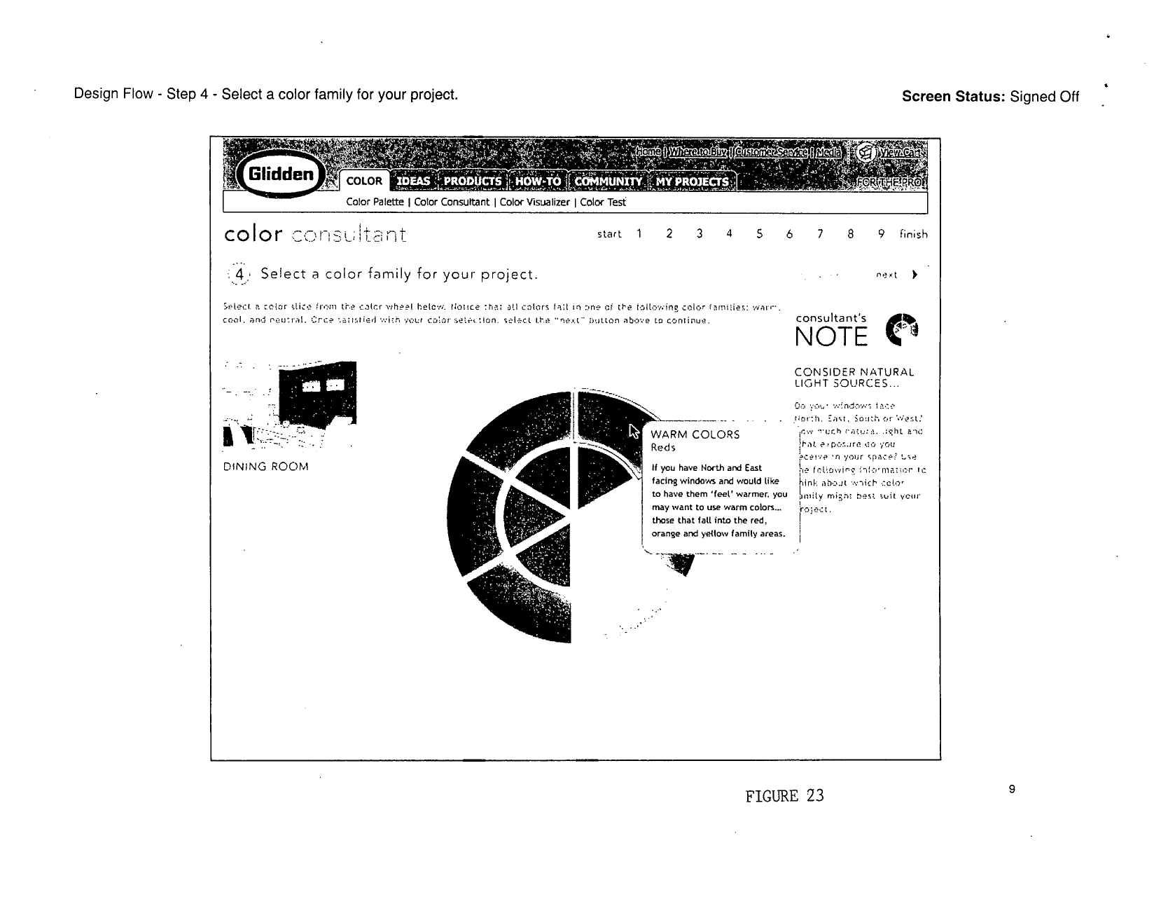

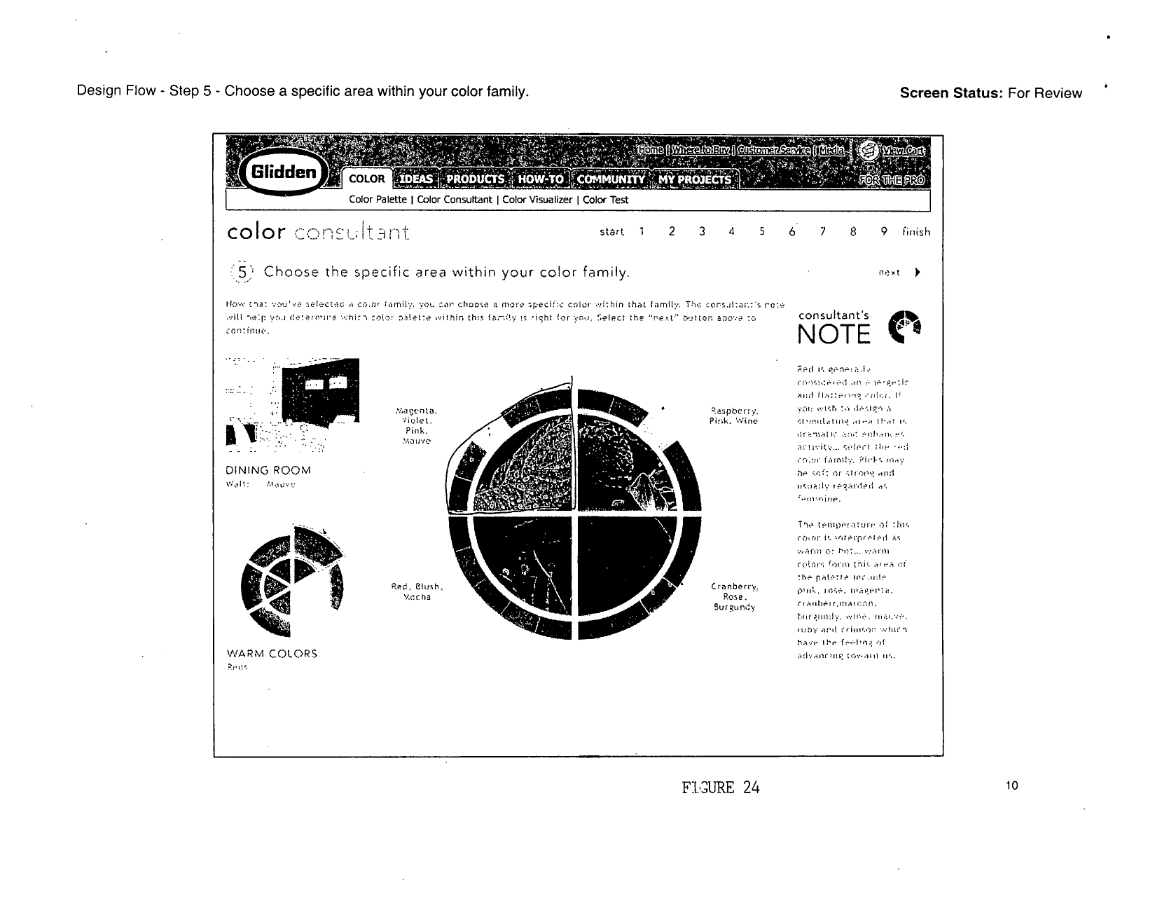

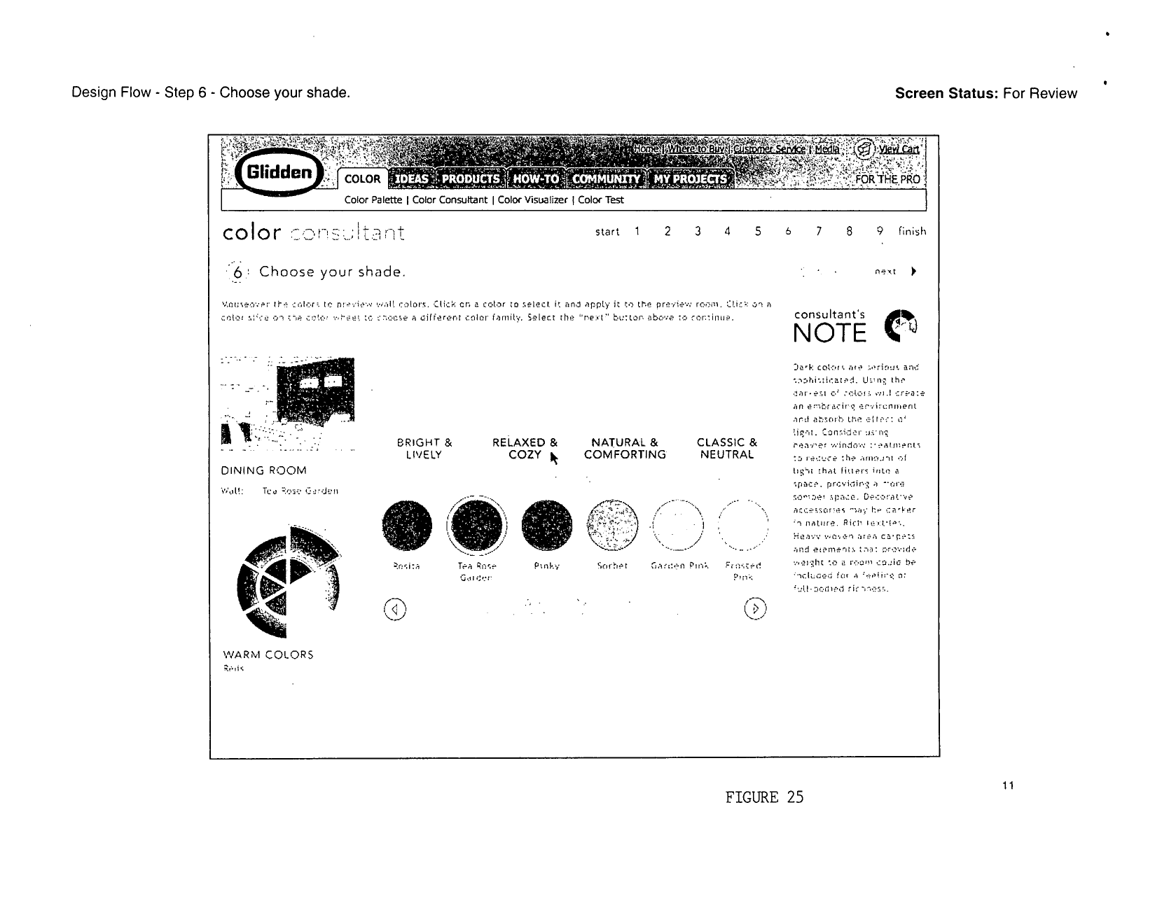

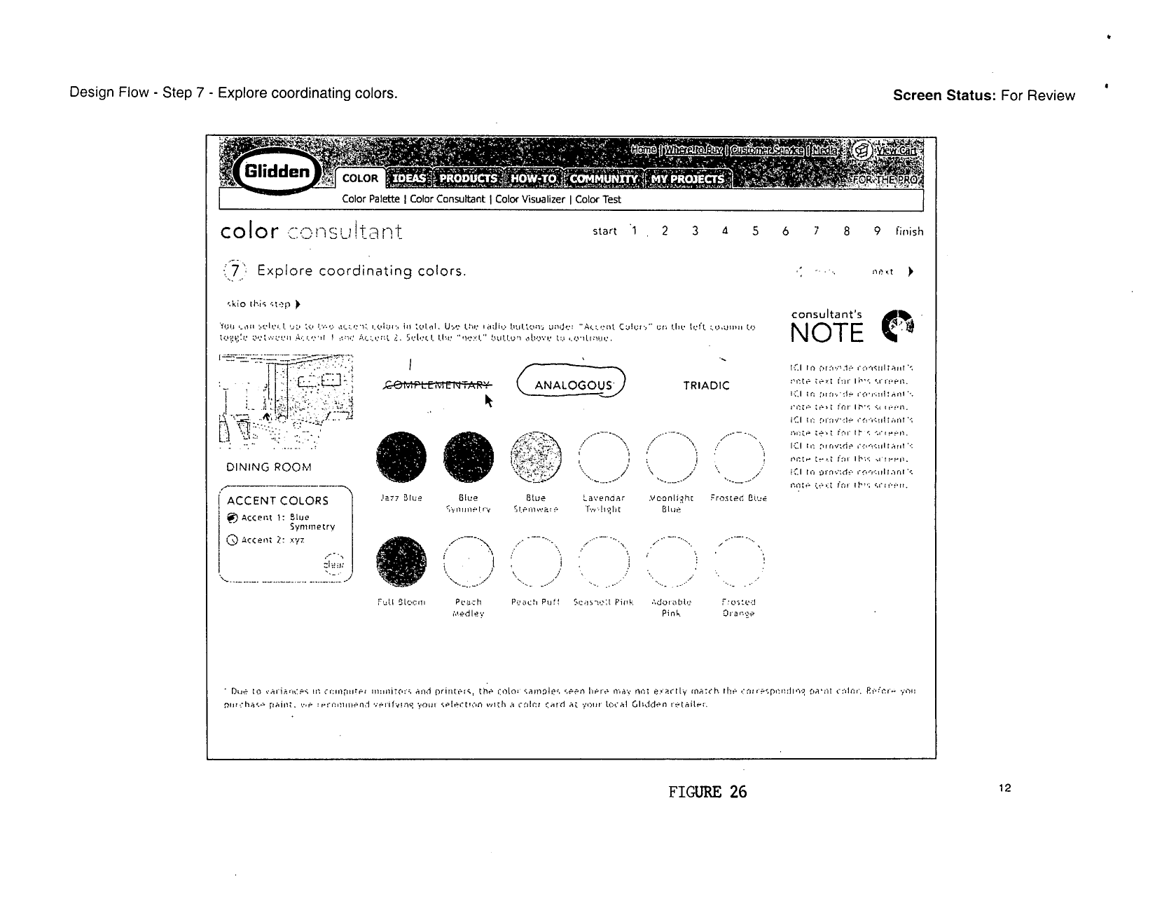

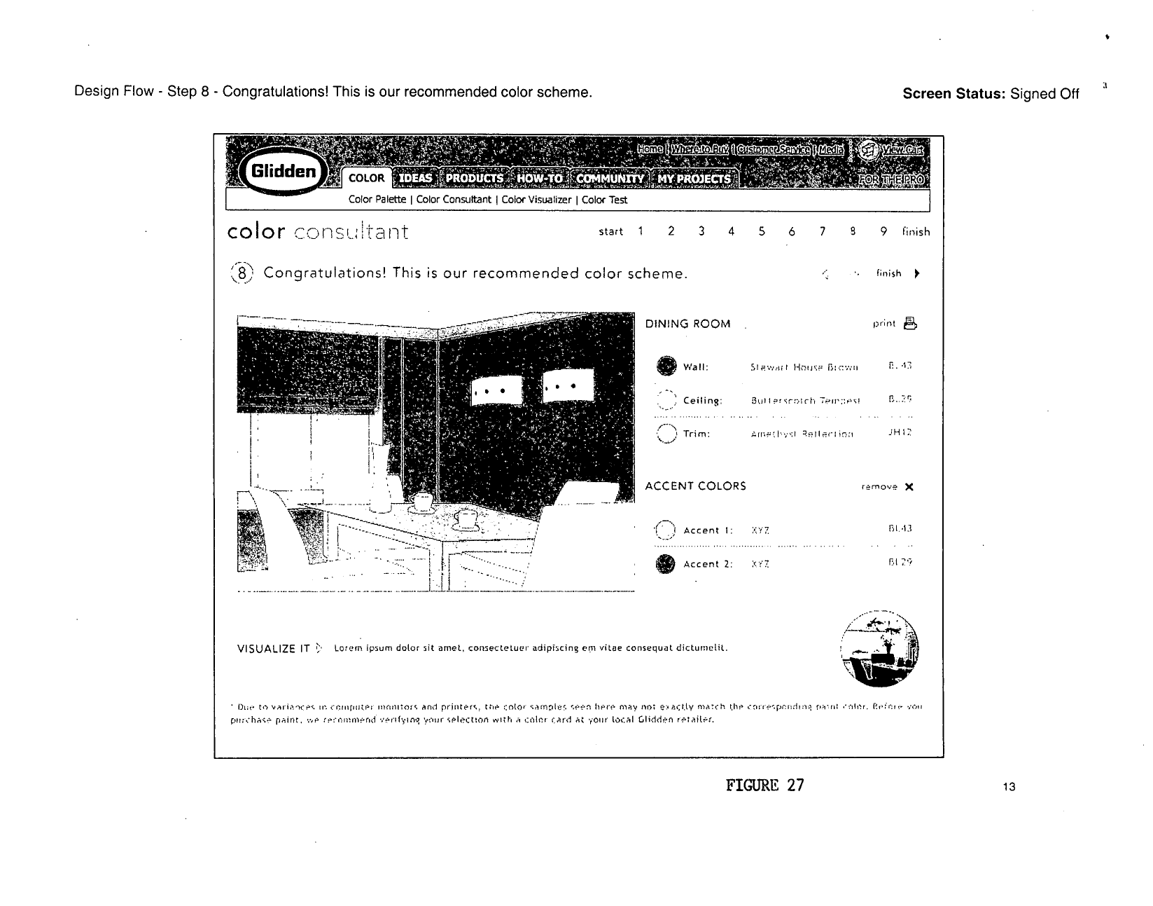

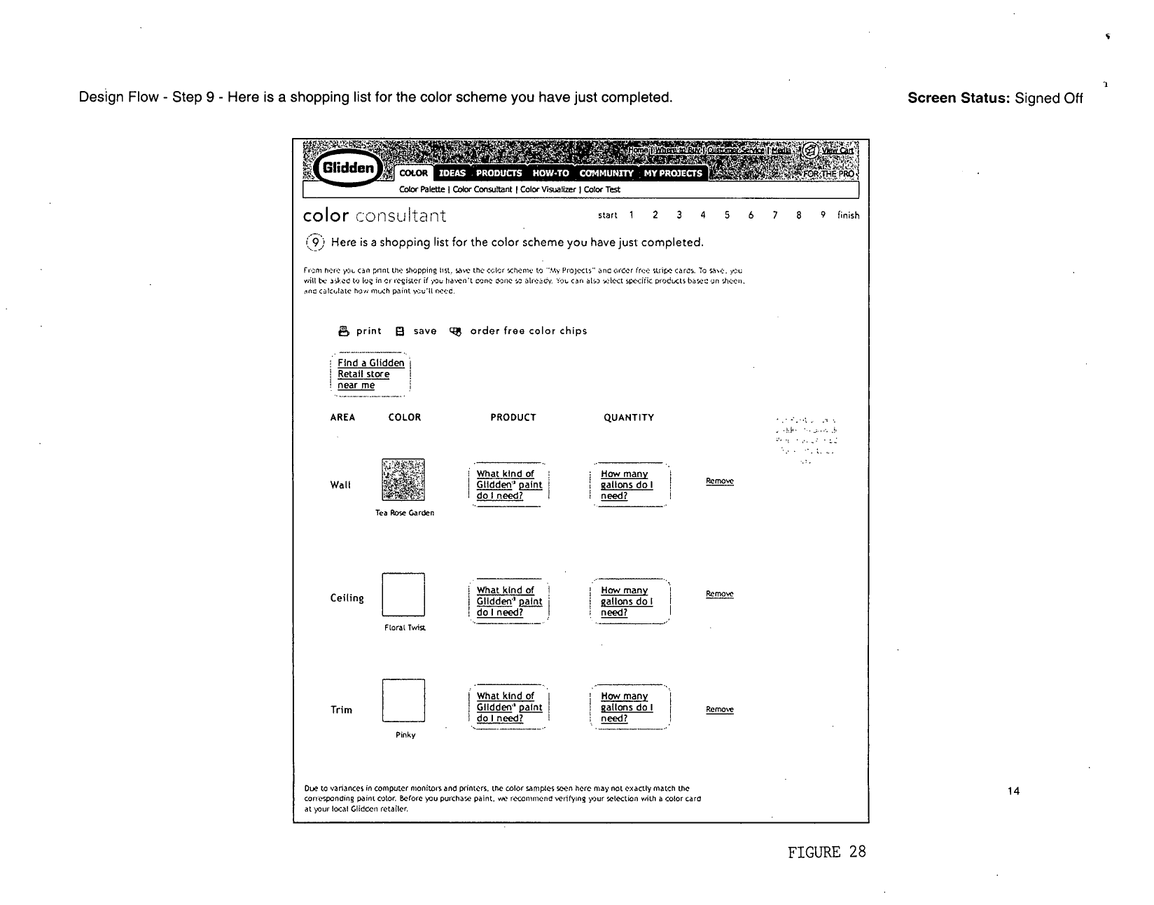

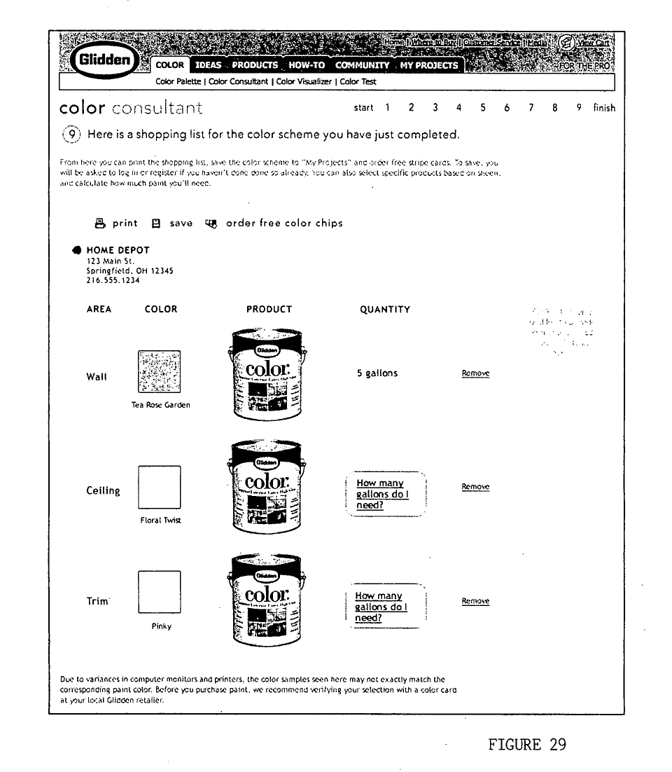

In one embodiment of the present invention the computer assisted process and system has graphic user interfaces for the process to assist the user in selecting color arrangements or schemes for surfaces. Non-exclusive examples of such interfaces are shown in the FIGS. 1-15. For this embodiment of the invention the process steps include:
1. selecting a color for use or refining a color or coordinate with existing colors for one or more surfaces;
2. selecting if the color scheme or arrangement such as for example that shown in Table I is for interior or exterior use;
3. selecting a arrangement of surfaces such as the exterior of a house or a room or some other architectural space with surfaces such as walls;
4. providing for two alternative routes for obtaining a color recommendation.

Alternative A is for exploring the full range of color within a color family for generating a main color and includes:
A1) providing information on the effect of natural and artificial light sources in a space and categorize color according to its temperature, such as for example that shown in Table II, to assist users in selecting a color family. Color family is defined by hue of color system notation. Hue follows the order of the rainbow and is divided into 8 color families. Each family can be further sub-divided into hue slices for instance that range from 00-99.
A2) Allowing for the selection of a color family based upon the information in step A1.
A3) Providing columns of color within the hue family and information on the effect of each hue family in a space.
A4) Allowing for the selection of a column of color within the hue family based upon the information in step A3.
A5) Providing a plurality of collections of effects for each color family dependent upon intensity and light reflectance. A non-exclusive example is four collections based upon any color system notation such as the Master Palette notation available from Imperial Chemical Industries PLC ICI Paints businesses. These collections include:
   i) Bright and Lively collection having high numeric values for intensity and relatively low light reflectance value.
   ii) Relaxed and Cozy collection defined by colors exhibiting lower values for intensity than Bright and Lively and have higher light reflectance values than Bright and Lively colors.
   iii) Classic and Neutral are the lightest colors in the system. These colors are defined by the highest light reflectance values and the lowest values for intensity.
   iv) Natural and comforting collection is defined completely by low values for intensity. This plurality of collections is more fully described in Table III
A6) Allowing for the selection of a collection based upon the information in step A5.
A7) Providing a number of shades of the color within the chosen collection and information on the effect of a light, medium or dark shade as defined by its intensity.
A8) Allowing for selection of primary color based upon the information in step 10.
A9) Providing one or more accent colors such as ceiling and trim color recommendation once the primary color is selected.
A10) Providing choices for at least one of: complementary, analogous and triadic schemes based upon primary color selection and information on how to incorporate those colors into the architectural space such as the same room or an adjoining room.

The second alternative includes create the color scheme around an established color comprising the steps of:
B1) providing a collection of effects for each color family dependent upon intensity and light reflectance. The system of A5) i through iv above can be used as a non-exclusive example.
B2) allowing for the selection of a collection based upon the information in step B1.
B3) providing information on the effect of natural and artificial light sources in a space and categorize color according to its temperature to assist users in selecting a color family. Color family is defined by hue on the master palette notation. Hue follows the order of the rainbow and is divided into 8 color families. Each family is further sub-divided into hue slices that range from 00-99.
B4) allowing for the selection of a color family based upon the information in step B3.
B5) providing columns of color within the hue family and information on the effect of each hue family in a space.
B6) allowing for the selection of a column of color within the hue family based upon the information in step B5.
B7) providing a number of shades of the color within the chosen collection and information on the effect of a light, medium or dark shade as defined by its intensity.
B8) allowing for selection of primary color based upon the information above.
B9) providing for accent colors such as a ceiling and/or trim color recommendation once the primary color is selected.
B10) providing for choices of at least one of complementary, analogous and triadic schemes based upon primary color selection and information on how to incorporate those colors into the same room or an adjoining room.

Optionally both alternatives include the one or more of the following steps:
C1) providing a comprehensive list of the information that is needed to purchase the paint in the selected color: sheen, quantity of paint and nearest store location.
C2) ordering stripe cards for selected colors for delivering by e-mail or paper mail services such as US Mail.
C3) allowing users to view chosen colors in a graphical depiction of a room such as a sketch of a room or a photographic image of a room.

A non-exclusive example of a series of questions posed to the user in the computer assisted process to arrive at a color scheme recommendation are show in Table IV.

TABLE I

| Color Scheme | Color Scheme Description |
|---|---|
| Monochromatic | A single color scheme that uses any shade, tint or tone of one color is a |
| | monochromatic scheme. This represents one hue, any hue from light to dark. |
| | This color scheme is the most restful and uncomplicated of all the schemes. It |
| | also assists in creating a more uniform appearance in any given space. |
| | Areas that are most suitable to this scheme include bedrooms, bathrooms, small |
| | spaces, hallways and other areas where you wish to incorporate a more calming |
| | atmosphere. |
| Analogous | Three colors neighboring each other on the color wheel represent an analogous |
| | scheme. |
| | This scheme incorporates colors that naturally flow from one to another creating |
| | a harmony of color. For inspiring combinations look to textiles, artwork and |
| | accessories. |
| | Areas that are most suitable for this scheme may be those that are next to each |
| | other in your home . . . those where you would like to create a flow of color from |
| | one space to another. |
| Complementary | Two colors opposite each other on the color wheel are a complementary |
| | scheme. |
| | This scheme begins to contrast two colors . . . and based on the depth or intensity |
| | will have varying results. Soft color contrasts will sparkle . . . while deeper colors |
| | will have a more dynamic effect. |
| | Areas that are most suitable to this scheme are entry areas, living rooms, |
| | children's rooms, dens and kitchens. |

TABLE II

| Color Category | Color Category Description |
|---|---|
| Warm Colors | Warm colors are the reds, oranges and yellows. |
| | An easy way to remember these are to think of things in nature that are |
| | warm . . . such as the sun, sand and autumn leaves. |
| | Consider that warm colors tend to advance towards us, creating a friendly |
| | atmosphere. |
| Cool Colors | Cool colors are the greens, blues and violets. |
| | An easy way to remember these are to think of things in nature that are |
| | cool . . . such as the sky, sea and grass. |
| | Consider that cool colors tend to recede away from us, creating a spacious |
| | feeling. |
| Neutral Colors | Neutral colors are found in the beige and gray areas. |
| | The beige colors include the warmer shades of off-white, tan, taupe, ivory, |
| | oyster, pearl, bronze and brown. The gray color area is considered cooler and |
| | includes tones of white, frost, charcoal, slate, graphite, onyx, silver and stone. |
| | These colors provide are extremely versatile and provide a comfortable |
| | atmosphere. |
| Color Scheme | Color Scheme Description |
| Off-White Colors | The off-whites comprise the full spectrum of color from the pinks to the violets. |
| | These essential off-whites capture the essence of radiance and offer balance when |
| | combining stronger colors of the palette. |
| | Whites have a timeless quality that offer enduring beauty throughout your home. |

TABLE III

| COLLECTION NAME | COLLECTION DESCRIPTION (Design Flow) |
|---|---|
| Bright & Lively | These are intense shades for spirited lifestyles . . . colors that will make a |
| | dynamic statement in your home. The strength and passion of this palette will |
| | allow you to establish a bold and dramatic atmosphere. |
| | If you wish to capture the full experience of color . . . you will be delighted with |
| | the vibrancy of this collection. Turn to these incredibly luscious colors to |
| | create the excitement and depth for which you have been searching. |
| Classic & Neutral | Our collection of whites showcase the very lightest and icy colors of the |
| | palette. This offering speaks to the simplicity we desire in our lives. |
| | Whites reflect the most light, enhance other colors and provide the feeling of |
| | a spacious atmosphere. We have included a complete spectrum of frosted |
| | colors that range from warm pinks to cool blues. |
| Natural & Comforting | These colors are nature's inspiration for refined tastes. Special tones that are |
| | absolutely tranquil and subtle . . . certain to create a most comforting |
| | environment. |
| | Capture a feeling of rich, inviting, deep and earthy color that will provide a |
| | home with the most sensuous color imaginable. |
| Relaxed & Cozy | These are enchanting colors that will create pleasing surroundings with a |
| | sense of harmony. Their softness gently embrace a room with wonderful color. |
| | Using these more restful shades will create a gentle elegance in your home. |
| | This truly thoughtful collection has a gracious style and inviting nature. |

TABLE IV

| | | | | |
|---|---|---|---|---|
| Step # | Question | Additional Page Text | Answer | Next Step |

VCC Questions

| | | | | |
|---|---|---|---|---|
| Intro | WELCOME to Glidden's Online | Together we'll have fun . . . , Together | Select route (Design It, Find It) | Design It, |
| | Decorating Center | we'll make decorating simple . . . , | | Find It |
| | | Together we'll create your perfect | | |
| | | home . . . By combining your own | | |
| | | personal color choices, along with | | |
| | | direction from our designers, we'll take | | |
| | | your through a step-by-step process of | | |
| | | selecting the ideal colors for your | | |
| | | home. | | |

(Interior) Design It Flow

| | | | | |
|---|---|---|---|---|
| 1 | What ROOM are you | n/a | choose an available room | 2 |
| | decorating? | | | |
| 2 | What kind of FEELING would | n/a | choose a color collection | 3 |
| | your like to create? | | | |
| 3 | Select a COLOR FAMILY for | n/a | choose a specific color family | 4 |
| | your project. | | | |
| 4 | Choose the specific area within | n/a | choose a color column | 5 |
| | your color family. | | | |
| 5 | Choose your SHADE. | n/a | choose one specific color for | 6 |
| | | | main wall | |
| 6 | CONGRATULATIONS! This is | n/a | Select route (Accent Colors, | 6.a, |
| | the color scheme that we | | Shopping List, Visualize It) | Shopping |
| | recommend for your room. | | | List, |
| | | | | Visualize It |
| 6.a | CONGRATULATIONS! This is | Choose Accent Colors | Choose scheme (Complemen- | Shopping |
| | the color scheme that we | | tary, Analogous, Triadic, | List, |
| | recommend for your room. | | Off-White) and then choose | Visualize It |
| | | | up to two specific colors | |
| | | | from any one scheme). | |
| | | | Select route (Visualize It, | |
| | | | Shopping List) | |
| Shopping List | Here's your SHOPPING LIST | Here's a shopping list of the color | Select Products, Calculate | Order Strip |
| | | scheme you have just completed. If | Paint Quantities. Select route (Order | Cards, Print, |
| | | you wish, you can print this list or save | Stripe Cards, Print, Save) | Save |
| | | it to your project planner. To save | | |
| | | your shopping list, you will be asked to | | |
| | | log in. You can also select products | | |
| | | and calculate how much paint you | | |
| | | need. | | |
| Visualize It | n/a | n/a | Visualizer is populated with | 6, 6.a |
| | | | default room (based on step 1) | |
| | | | and users selected color | |
| | | | scheme. Option to go back to | |
| | | | VCC Design. | |

Find It Flow

| | | | | |
|---|---|---|---|---|
| 1 | What ROOM are you | n/a | choose an available room | 2 |
| | decorating? | | | |
| 2 | Select a COLOR FAMILY for | n/a | choose a specific color family | 3 |
| | your project. | | (if a Off-White or Neutral | |
| | | | color family is selected, | |
| | | | skip step 4 - Mood) | |
| 3 | Choose the specific area within | n/a | choose a color column. If an | 4, 5 |
| | your color family. | | Off-white or Neutral color | |
| | | | family was selected on the | |
| | | | previous step, we skip the | |
| | | | next step of Mood. | |
| 4 | What kind of FEELING would | n/a | choose a color collection or | 5 |
| | your like to create? | | Mood. | |
| 5 | Choose your SHADE. | n/a | choose one specific color for | 6 |
| | | | main wall | |
| 6 | CONGRATULATIONS! This is | n/a | Select route (Accent | 6.a, |
| | the color scheme that we | | Colors, Shopping List, | Shopping |
| | recommend for your room. | | Visualize It) | List, |
| | | | | Visualize It |
| 6.a | CONGRATULATIONS! This is | Choose Accent Colors | Choose scheme (Complemen- | Shopping |
| | the color scheme that we | | tary, Analogous, Triadic, | List, |
| | recommend for your room. | | Off-White) and then choose | Visualize It |
| | | | up to two specific colors | |
| | | | from any one scheme). Select route | |
| | | | (Visualize It, Shopping List) | |
| Shopping List | Here's your SHOPPING LIST | Here's a shopping list of the color | Select Products, Calculate | Order Strip |
| | | scheme you have just completed. If | Paint Quantities. Select route (Order | Cards, Print, |
| | | you wish, you can print this list or save | Stripe Cards, Print, Save) | Save |
| | | it to your project planner. To save | | |
| | | your shopping list, you will be asked to | | |
| | | log in. You can also select products | | |
| | | and calculate how much paint you | | |
| | | need. | | |
| Visualize It | n/a | n/a | Visualizer is populated with | 6, 6.a |
| | | | default room (based on step 1) | |
| | | | and users selected color scheme. | |
| | | | Option to go back to VCC | |
| | | | Design. | |

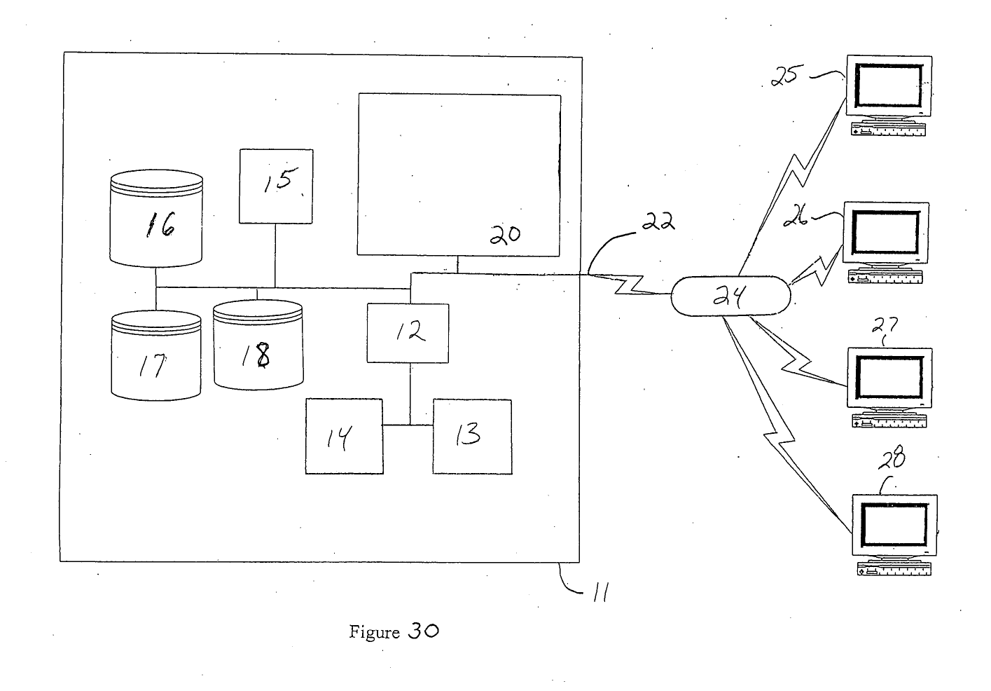

FIG. 30 illustrates one suitable embodiment of the present disclosure showing a computer network system for use on line. The system includes a computer system 11. The computer system 11 can have a central processing unit (CPU) 12 for processing data and program instructions. The computer system 11 also includes input and output devices, as is well known in the art. For example, the computer 11 can include a display screen or monitor 13, a keyboard 14 of course a mouse (not shown) can also be included as well as a printer (not shown), and the like as known to those skilled in the art. The computer system 11 further can include data storage and memory devices, as are known in the art, for storing the color database 16, the structural artifact database 17, the expert advise database 18, an application program 20 and a browser 15. The color database 16 is used to store and manage the various colors of a paint palette and can include the coordinating colors that are complementary, analogous, and/or triadic along with the color collection information. The structural artifact database 17 is used to store the images that can be auto-populated with the selected colors or have drag and drop color insertion with a suitable drag and drop application computer software. Additional databases can be included to store the additional features for example the expert advise and questions for user database 18 which gives information about the colors and the structure artifacts for the user to make a selection to apply a color to the structural artifact. The databases 16-18 can be relational databases, as are well known in the art. The computer system 11 as web server is connected to a network 24, which serves as a communications medium with a plurality of user computers indicated by computers 25, 26, 27, and 28. However there can be any number of users.

Of course the system of the present invention can also involve Storage Area Network (SAN) connecting data and components to other components. Also, network connections such as (e.g., Wide Area Network (WAN), Local Area Network (LAN), etc.) to system of the invention are a possibility that reside outside of the server system itself. As for the internet it is any global network of computers. One popular part of the Internet is known as the World Wide Web, or the “Web.” The Web contains computers capable of displaying graphical and/or textual content or information. Computers that provide information on the Web are typically called “web sites.” A website is defined by an Internet address referred to as a “URL” (uniform resource locator, e.g. http://www.glidden.com) that has an associated electronic page, often called a “home page.” The URL has the access protocol of (http), the domain name (www.specdoctor.com) and optionally can include a path such as (http://www.glidden.com/home/indexjsp#) for the Color Consultant to a file or resource residing on that server. This URL and its contents are hereby incorporated by reference. Generally, a home page is an electronic document that organizes the presentation of one or more of such items as: text, graphical images, audio and video into a desired display. Such a home page can be a single page or a plurality of web pages which constitute a file written usually in hypertext markup language (HTML) or derivatives thereof such as extensible HTML (XHTML) and which is stored on a web server. As noted above the web page can include other features such as images that appear as part of the page when it is displayed by a web browser.

Of course as understood by those skilled in the art, where appropriate for the given state of computer hardware, existence of internal networks, and available software, other configurations of a network are possible including wireless networks.

In one embodiment, the present invention can be a Web-based system and method that utilizes HyperText Markup Language (HTML) to implement documents on the Internet together with a general-purpose secure communication protocol for a transport medium between the web-based system and the internet user. HTTP or other protocols could be readily substituted for HTML without undue experimentation. Information on these products is available in T. Bemers-Lee, D. Connoly, “RFC 1866: Hypertext Markup Language —2.0” (November 1995); and R. Fielding, H, Frystyk, T. Bemers-Lee, J. Gettys and J.C. Mogul, “Hypertext Transfer Protocol--HTTP/1.1: HTTP Working Group Internet Draft” (May 2, 1996). HTML is a simple data format used to create hypertext documents that are portable from one platform to another. HTML documents are SGML documents with generic semantics that are appropriate for representing information from a wide range of domains. HTML has been in use by the Web global information initiative since 1990. HTML is an application of ISO Standard 8879; 1986 Information Processing Text and Office Systems; Standard Generalized Markup Language (SGML).

Another approach for at least one embodiment of the present invention is with Java, where User Interface (UI) components can include custom items such as: real-time information, animated icons, and the like. Unlike HTML, Java supports the notion of client-side validation, offloading appropriate processing onto the client for improved performance. Dynamic, real-time Web pages can be created. Sun's Java language is defined as: “a simple, object-oriented, distributed, interpreted, robust, secure, architecture-neutral, portable, high-performance, multithreaded, dynamic, buzzword-compliant, general-purpose programming language. Java which has become an industry-recognized language for “programming the Internet supports programming for the Internet in the form of plafform-independent Java applets.” Java applets are small, specialized applications that comply with Sun's Java Application Programming Interface (API) allowing developers to add “interactive content” to Web documents (e.g., simple animations, page adornments, and the like). Applets execute within a Java-compatible browser (e.g., Netscape Navigator) by copying code from the server to user. From a language standpoint, Java's core feature set is based on C++. Sun's Java literature states that Java is basically, “C++ with extensions from Objective C for more dynamic method resolution.”

Of course other technologies than JAVA known to those skilled in the art can be used such as Microsoft and ActiveX Technologies. ActiveX includes tools for developing animation, 3-D virtual reality, video and other multimedia content. The tools use Internet standards, work on multiple platforms, and these are being supported by more companies over time. The building blocks are called ActiveX Controls that are small and fast components that enable embedding of parts of software in hypertext markup language (HTML) pages. ActiveX Controls work with a variety of programming languages including Microsoft Visual C++, Borland Delphi, Microsoft Visual Basic programming system and Microsoft's development tool for Java. ActiveX Technologies also includes ActiveX Server Framework, allowing developers to create server applications.

In certain implementations of the invention, a server system is connected to one or more user systems via a network (e.g., the Internet). The server system performs many functions, including, for example: enabling user software to log into the server system and request and access data; uploading data from user software; retrieving and using data from a data store; generating data layers (e.g.,.spatially referenced images); sending data to the user software for display; and, handling various notifications to the user software (e.g., a notification regarding new data added to the data store).

The system of the present invention can suitably provide browser support. In particular, the system software is a web-based application service provider (ASP) that supports, for example, the following browsers: Microsoft®. Internet Explorer®. version 4.x and above and Netscape®5.x and above.

The system can provide for and/or use or display content that can include: a technique for receiving spatial and tabular updates from a handoff to a third party system using an interface technique, such as Web Services (which is a standard, flexible connection technique to allow communication between disparate computer systems using Internet or similar network connection to transfer information and may be used to send XML messages). Moreover, the system may provide a spatial editor for modifying editable data elements (e.g., graphical objects or tabular data, and the like known to those skilled in the art.), while the third party system may implement business rules for validating the editable data elements.

Also, the system may involve data compression (e.g., of image data) at run time during the data transformation stage. Compressing data is important because some data (e.g., GIS image data) cannot be accessed over the Internet due to the size of the data. For example, some image data is in a graphical data format called TIFF. TIFF, as understood by those skilled in the art, is a tag-based image file format that is designed to promote the interchange of digital image data. TIFF provides a multi-purpose data format and is compatible with a wide range of scanners and image-processing applications. TIFF format is device independent and is used in most operating environments, including Windows®, Macintosh®, and UNIX®. TIFF is a popular and flexible public domain raster file format. To be able to use GIS image data that may be transferred over the Internet, implementations of the invention convert large image data to a compressed data format, such as JPEG. There are many reasons for using the JPEG file format. JPEG permits a greater degree of compression than other image formats, such as TIFF, enabling quicker downloading times for larger graphics. Furthermore, JPEG documents appear to retain almost complete image quality for most photographs.

We claim:

1. Process for computer assisted selection of at least one color scheme, comprising:
presenting on a computer display device through a graphic user interface an option for selecting at least one color scheme from an established color in the a color database and selecting at least one color scheme for a generated color in the color database;
allowing through a graphic user interface a selection from at least one database an architectural surface from a database of a plurality of architectural surfaces;
presenting on the computer display a plurality of color design questions concerning a plurality of collections of color arranged with each collection having at least 5 color families wherein the collections vary one from the other in the range of chroma and/or reflectance value for at least 50 hue slices for the color families;
allowing through a graphic user interface the selection of a main color and at least one coordinating color selected from complementary, analogous, and triadic color to the main color as accent colors through response to the questions; and
presenting on the computer display a recommended color scheme with a main color and at least one accent color that is complementary or analogous or triadic to the main color.

2. System of the process of claim 1 having a computer display device communicating with an operating system, computer memory, and at least the architectural surface and color databases.

3. System of claim 2 wherein the communicating is by the internet.

4. Process for computer assisted selection of at least one color scheme for a structure or part of a structure to be painted, comprising:
a) accessing a web site on the internet through a remote computer display device;
b) providing at the web site for selection through a graphic user interface an option for selecting at least one color scheme from an established color in a color database and selecting at least one color scheme for a generated color from the color database;
c) providing at the web site for selection through a graphic user interface images of structural archetypes that closely match the structure to be painted that can be imaged to depict at least one selected color for at least one surface shown in the image, where the images of structural archetypes are in another database;
d) providing a series of questions concerning a plurality of collections of color arranged with each collection having at least 5 color families wherein the collections vary one from the other in the range of chroma and/or reflectance value for at least 50 hue slices for the color families for selection of at least one color and at least one differing shade to a plurality of colors from at least one database;
e) providing color selection advice regarding the color, and the color's mood and the location of the structural archetype to be painted from at least one database;
f) applying the at least one selected color to the image to produce a color scheme for the image; and
g) displaying the structure or part of a structure with the color applied and providing information from which paint corresponding to the color or colors in the color scheme can be identified for purchase or use.

5. Process according to claim 4 where the structural archetypes are images of a building.

6. Process of claim 5 where the image is of the interior of a building selected from at least one of hall or entry way, living room, kitchen, dining room, family room, den, and bedroom.

7. Process of claim 5, wherein the building is a house.

8. Process of claim 5, where separate areas of the archetypes can be colored separately one from another.

9. Process of claim 6, where the archetype is an interior of a building having walls, doors, coving, ceiling, dado rails, skirting boards, window frames, sills and fireplaces.

10. Process according to claim 4 where the archetype is an interior of a building and also contains furniture or furnishings.

11. Process according to claim 4 where the images are photographic quality.

12. Process according to claim 4 where the colors are assembled in groups in which the colors are complimentary or contrasting one with another.
